(19) United States
(12) Patent Application Publication
(10) Pub. No.: US 2025/0047252 A1
(43) Pub. Date: Feb. 6, 2025

(54) SINGLE-ENDED AMPLIFIER WITH BIAS STABILIZATION

(71) Applicant: MACOM Technology Solutions Holdings, Inc., Lowell, MA (US)

(72) Inventors: Duy NGUYEN, San Jose, CA (US); Ray MORONEY, Carlisle, MA (US); Stefano D'AGOSTINO, Los Altos, CA (US); Trong PHAN, Garden Grove, CA (US)

(21) Appl. No.: 18/292,231

(22) PCT Filed: Aug. 31, 2022
(86) PCT No.: PCT/US2022/075737

§ 371 Date: Jan. 25, 2024

Related U.S. Application Data
(60) Provisional application No. 63/248,751, filed on Sep. 27, 2021.

(51) Int. Cl. H03F 3/45

(52) U.S. Cl. CPC H03F 3/45475

(57) ABSTRACT

Aspects of an amplifier with bias stabilization are described. In one example, an amplifier includes an output amplifier stage having an input terminal, a biasing leg having a biasing node coupled to the input terminal, and a bias feedback network coupled between the input terminal of the output amplifier stage and the biasing leg. The bias feedback network can include a difference amplifier, a bypass stage, and a reference voltage generator in one example. The difference amplifier can generate a bias control signal based on a difference between a bias voltage at a base terminal of the output amplifier stage and a voltage reference generated by the reference voltage generator. The bias feedback network generates the bias control signal and controls the bias voltage based on feedback, to keep the bias voltage and bias current constant over process, temperature, gain and other variations for consistent performance.

### BACKGROUND

This application claims the benefit of and priority to U.S. Provisional Patent Application No. 63/248,751, filed Sep. 27, 2021, titled “SINGLE-ENDED AMPLIFIER WITH BIAS STABILIZATION,” the entire contents of which is hereby incorporated herein by reference.

### BACKGROUND

An amplifier is an electronic circuit or device designed to increase the power level of an input signal. Amplifiers are typically designed to have linear gain over at least a certain frequency range or bandwidth. Amplifiers can be defined according to the properties of their outputs to their inputs, among other characteristics. As one example, gain can be defined as the ratio between the magnitudes of the output and input signals of an amplifier, and gain can be unitless and expressed in decibels. Amplifiers are typically designed to have linear gain over a certain operating frequency range or bandwidth, although amplifiers can also be designed to achieve a range of different performance characteristics depending upon the application. Other characteristics of amplifiers can be defined according to other input and output characteristics, small signal parameters, scattering parameters, and other operating characteristics.

Transistors are commonly used as amplifiers or as parts of amplifier circuits. A transistor, such as a bipolar junction transistor (BJT), can be configured as a certain type or class of amplifier based on which terminal of the transistor is common to both the input and the output of the transistor. In the case of bipolar junction transistors, the amplifier classes include common emitter, common base, and common collector. For field-effect transistors (FETs), the amplifier classes include common source, common gate, and common drain.

### SUMMARY

Amplifiers with bias stabilization are described herein. In one example, an amplifier includes an output amplifier stage having an input terminal, a biasing leg having a biasing node coupled to the input terminal, and a bias feedback network coupled between the input terminal of the output amplifier stage and the biasing leg. The bias feedback network can include a difference amplifier, a bypass stage, and a reference voltage generator in one example. The difference amplifier can generate a bias control signal based on a difference between a bias voltage at a base terminal of the output amplifier stage and a voltage reference generated by the reference voltage generator. The bias feedback network generates the bias control signal and controls the bias voltage based on feedback, to keep the bias voltage constant over process, temperature, gain and other variations for consistent performance of the amplifier.

In one aspect of the embodiments, the biasing leg includes a first biasing transistor and a second biasing transistor. The first biasing transistor includes a collector coupled to a source voltage, an emitter coupled to the second biasing transistor, and a base coupled to an input of the amplifier. The second biasing transistor includes a collector coupled to the first biasing transistor, an emitter coupled to ground, and a base coupled to a bias control signal from the bias feedback network. In other aspects, the biasing leg further includes a voltage drop resistor coupled in series between the emitter of the first biasing transistor and the collector of the second biasing transistor. The biasing node of the biasing leg is positioned between the voltage drop resistor and the collector of the second biasing transistor.

In other aspects of the embodiments, the bias feedback network includes a difference amplifier, a bypass stage, and a reference voltage generator. The first input of the difference amplifier is coupled to the input terminal of the output amplifier stage, and the second input of the difference amplifier is coupled to an output of the reference voltage generator. The difference amplifier generates a bias control signal based on a difference between the first input and the second input of the difference amplifier. The bias control signal is coupled as an input to the biasing leg. The bias control signal controls a potential at the biasing node in the biasing leg, which is coupled to the input terminal of the output amplifier stage.

In other aspects, an operating bandwidth of the difference amplifier is smaller than an operating bandwidth of the output amplifier stage. The output amplifier stage can be embodied as a bipolar junction transistor. The output amplifier stage can also be embodied as a base-biased bipolar junction transistor. The base-biased bipolar junction transistor can be embodied as a Silicon Germanium (SiGe) bipolar junction transistor, in one example, although other types of transistor amplifiers can be relied upon for the output amplifier stage.

In another example, an amplifier with bias stabilization includes a single-ended output transistor stage having an input terminal at a base of the transistor stage, where the transistor stage is base-biased. The amplifier also includes a biasing leg having an input for the amplifier and a biasing node coupled to the input terminal of the output transistor stage. The amplifier also includes a bias feedback network coupled between the input terminal of the output transistor stage and the biasing leg.

In one aspect of the embodiments, the biasing leg includes a common collector input transistor and a common emitter biasing transistor. The biasing leg also includes a voltage drop resistor coupled in series between an emitter of the common collector input transistor and a collector of the common emitter biasing transistor. The biasing node of the biasing leg is positioned between the voltage drop resistor and the collector of the common emitter biasing transistor.

In other aspects of the embodiments, the bias feedback network includes a difference amplifier and a reference voltage generator. The difference amplifier generates a bias control signal based on a difference between the input terminal of the output transistor stage and the reference voltage generator, and the bias control signal is coupled to the biasing node of the biasing leg.

In another example, an amplifier with bias stabilization includes a single-ended output transistor stage, a biasing leg including an input for the amplifier and a biasing node coupled to an input terminal of the output transistor stage, and a bias feedback network coupled between the input terminal of the output transistor stage and the biasing leg. The biasing leg includes a common emitter input transistor and a common collector biasing transistor, and a voltage drop resistor coupled in series between an emitter of the common emitter input transistor and a collector of the common collector biasing transistor. The biasing node of the biasing leg is positioned between the voltage drop resistor and the collector of the common collector biasing transistor.

In aspects of the embodiments, the bias feedback network comprises a difference amplifier and a reference voltage generator, the difference amplifier generates a bias control signal based on a difference between the input terminal of the output transistor stage and the reference voltage generator, and the bias control signal is coupled to the biasing node of the biasing leg.

### BRIEF DESCRIPTION OF THE DRAWINGS

Aspects of the present disclosure can be better understood with reference to the following drawings. It is noted that the elements in the drawings are not necessarily drawn to scale, with emphasis instead being placed upon illustrating the principles of the examples. In the drawings, like reference numerals designate like or corresponding, but not necessarily the same, elements throughout the several views.

FIG. 1 illustrates a differential amplifier according to various examples described herein.

FIG. 2 illustrates a block diagram for a single-ended amplifier with bias stabilization according to various aspects of the embodiments described herein.

FIG. 3 illustrates a single-ended amplifier with bias stabilization according to various aspects of the embodiments described herein.

### DETAILED DESCRIPTION

As noted above, transistors are commonly used as amplifiers. A transistor can be configured as a certain type or class of amplifier based on which terminal of the transistor is common to both the input and the output circuit. In the case of single bipolar junction transistors, the amplifier classes include common emitter, common base, and common collector. For single field-effect transistors, the amplifier classes include common source, common gate, and common drain. A number of transistors can also be coupled together to form larger and more complex amplifier circuits including one or more amplifier stages. Examples of such amplifier circuits include differential amplifiers, distributed amplifiers, amplifiers including dedicated preamplifier, low-noise, output, and other stages.

The design of an amplifier includes the evaluation of a number of operating characteristics of the amplifier, such as amplifier biasing, gain, operating bandwidth, input and output characteristics, small signal parameters, stability, and other operating characteristics. The stability of an amplifier, as one operating characteristic, can depend on the type (e.g., semiconductor structure and materials), biasing, power, temperature, bandwidth, and other factors related to the amplifier and the application, and it is important to evaluate the stabilization characteristics and refine the stabilization approach for each amplifier design. A number of approaches can be relied upon to stabilize amplifiers for various purposes. As one example, to stabilize a common gate transistor over a frequency range, shunt-connected gate capacitors, shunt-connected resistor-capacitor gate networks, drain-to-gate resistor-capacitor networks, combinations thereof, and other gate-connected networks of resistors and capacitors can be relied upon. Appropriate amplifier biasing is also important for the stability of amplifiers, and amplifier biasing should account for the operational input biasing and output range of the amplifier, among other considerations. The approach relied upon to stabilize one type of amplifier for one application may not be suitable to stabilize another type of amplifier for another application.

Single-ended amplifiers offer certain benefits, such as simplicity in design and implementation, without the need for output impedance balancing, which is typically needed for other amplifier topologies. Transistor biasing can be a particular concern in some configurations of single-ended amplifiers. For example, a bipolar transistor output amplifier stage may be biased for operation at its base terminal, which is particularly sensitive over process, voltage, and temperature ranges. A measure of the current output at the collector of such an output amplifier stage is an exponential function of the potential at the base of the transistor. Even a minor change in bias voltage provided to the base of the output amplifier stage can result in a significant variation in collector current, altering or degrading the performance of the amplifier.

In the context outlined above, aspects of a single-ended amplifier with bias stabilization are described herein. In one example, a single-ended amplifier includes an output amplifier stage having an input terminal, a biasing leg having a biasing node coupled to the input terminal, and a bias feedback network coupled between the input terminal of the output amplifier stage and the biasing leg. The bias feedback network can include a difference amplifier, a bypass stage, and a reference voltage generator in one example. The difference amplifier can generate a bias control signal based on a difference between a bias voltage at a base terminal of the output amplifier stage and a voltage reference generated by the reference voltage generator. The bias feedback network generates the bias control signal and controls the bias voltage based on feedback, to keep the bias voltage constant over process, temperature, gain and other variations for consistent performance of the amplifier.

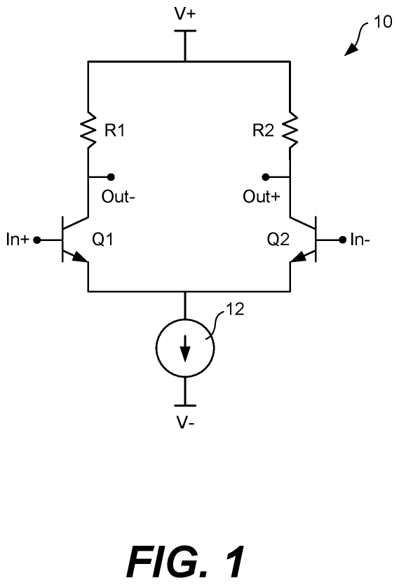

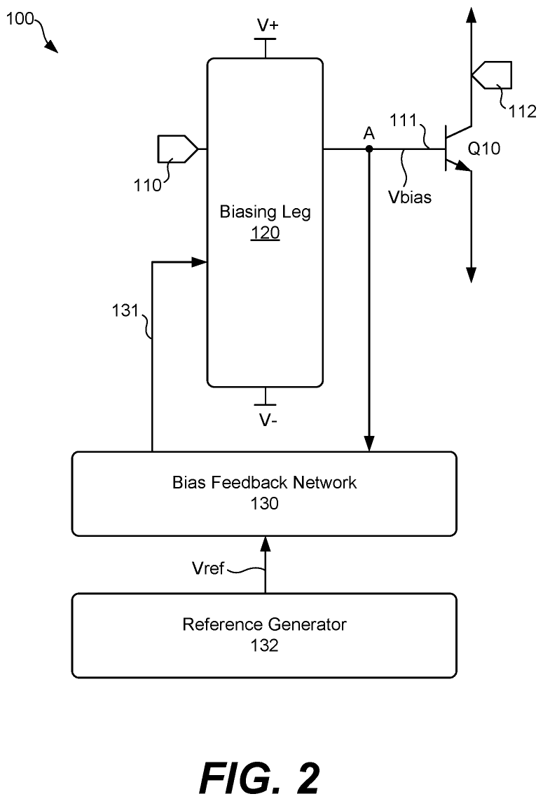

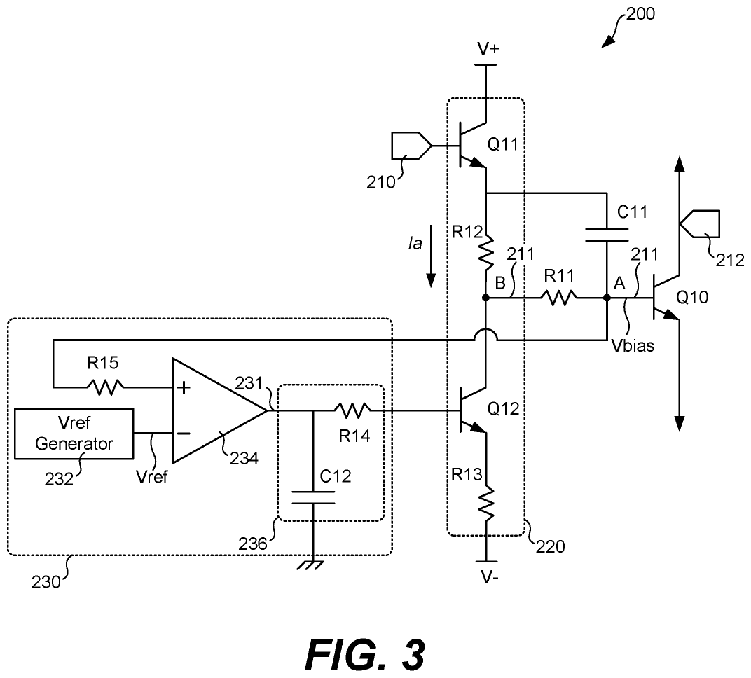

Turning to the drawings, FIG. 1 illustrates a differential amplifier 10 according to various examples described herein. The differential amplifier 10 can be embodied in various ways, such as using discrete components, as an integrated circuit device formed on one or more substrates, or as a combination of discrete components and integrated devices. The differential amplifier 10 is provided as a representative example of a conventional differential amplifier, to be contrasted with the single-ended amplifiers and the single-ended amplifiers with bias stabilization described below with reference to FIGS. 2 and 3.

The differential amplifier 10 is operated between source and sink voltages or potentials V+ and V−, respectively. The differential amplifier 10 includes transistors Q1 and Q2, resistors R1 and R2, and a current source 12. The emitters of the transistors Q1 and Q2 are electrically coupled to the current source 12, and the current source 12 is coupled between the emitters of the transistors Q1 and Q2 and the sink voltage V−. The current source 12 provides a constant current bias for operation of the differential amplifier 10. The current source 12 can be embodied as a current mirror in one example, although other types of current sources can be relied upon. The transistors Q1 and Q2 can be embodied as bipolar junction transistors in the example shown. The concepts described herein are not limited to any particular type of transistors, however, as the concepts are applicable to other types of transistors and active devices.

The resistors R1 and R2 are coupled, respectively, between the source voltage V+ and the collectors of the transistors Q1 and Q2. The base of the transistor Q1 serves as a non-inverting input In+ of the differential amplifier 10. The base of the transistor Q2 serves as an inverting input In− of the differential amplifier 10. The collector of the transistor Q1 serves as an inverting output Out− of the differential amplifier 10, and the collector of the transistor Q2 serves as a non-inverting output Out+ of the differential amplifier 10.

The source voltage V+ can be any suitable voltage depending on the application for the differential amplifier 10, and the sink voltage V− can be any suitable voltage or potential less (e.g., ground potential in some cases) than the source voltage V+. The difference in potential between the source voltage V+ and the sink voltage V− can be any suitable potential difference, such as a potential difference between the range of 50V to 3V, for example, although larger or smaller potential differences can be relied upon.

The differential amplifier 10, and variations of the differential amplifier 10, are useful in a wide range of applications. As examples, the differential amplifier 10 can be used in single and dual input configurations, in balanced and unbalanced output configurations, and in other configurations. The differential amplifier 10 is not ideal for all purposes, however. As one example, if an output of the differential amplifier 10 is taken at the Out+ output, it can be helpful and sometimes necessary to terminate the Out-output with a matched impedance to ground, so that the differential amplifier 10 sees a balanced output impedance. This termination can result in lost or wasted power, as the matched impedance is only relied upon for impedance matching.

Single-ended amplifiers offer benefits as compared to differential amplifiers, including the differential amplifier 10, in some cases. However, transistor biasing can be a particular concern in some configurations of single-ended amplifiers. For example, a bipolar transistor output amplifier stage may be biased for operation at its base terminal, which is particularly sensitive over process, voltage, and temperature ranges. The current at the collector of a base-biased output amplifier stage is an exponential function of the potential at the base of the transistor. Thus, even a minor change in bias voltage provided to the base of the output amplifier stage can result in a significant variation in collector current, altering or degrading the performance of the amplifier. Bias stabilization and related techniques for single-ended amplifiers are described below with reference to FIGS. 2 and 3. While the concepts are described in connection with bipolar transistors in the examples, the concepts can be extended to other types of transistors, including FETs. Thus, references to the base of a bipolar transistor also apply to the gate of a FET. References to the emitter of a bipolar transistor also apply to the source of a FET, and references to the collector of a bipolar transistor also apply to the drain of a FET.

FIG. 2 illustrates a single-ended amplifier 100 with bias stabilization according to various aspects of the embodiments described herein. The amplifier 100 can be used as a driver amplifier for optical communications, for radio frequency (RF) communications, or for other purposes, without limitation. The amplifier 100 incorporates circuitry for bias stabilization, as described in further detail below, and the amplifier 100 is provided as an example of an amplifier that incorporates the concepts of bias stabilization described herein. Other types and configurations of amplifiers can also incorporate the bias stabilization concepts.

Among possibly other components, the amplifier 100 includes an input 110, an output 112, a biasing leg 120, a bias feedback network 130, a reference generator 132, and an output amplifier stage Q10. The output amplifier stage Q10 is shown as a bipolar junction transistor in FIG. 2. The output amplifier stage Q10 includes a base terminal, a collector terminal, and an emitter terminal. The collector of the output amplifier stage Q10 is coupled to an upper rail voltage or other voltage or power source for the amplifier 100, and the collector of the output amplifier stage Q10 is coupled to a lower rail voltage or ground for the amplifier 100. In some cases, a resistor or resistor network can be coupled between the collector of Q10 and the upper rail voltage source. Similarly, a resistor or resistor network can be coupled between the emitter of Q10 and the lower rail voltage or ground in some cases.

The output amplifier stage Q10 is base-biased between the upper rail voltage or other voltage or power source and the lower rail voltage for the amplifier 100. The base terminal of the output amplifier stage Q10 is electrically coupled at the node A in FIG. 2. As described in further detail below, the output amplifier stage Q10 is biased at the node A based on the operation of the biasing leg 120 and the bias feedback network 130.

The output amplifier stage Q10 can be embodied as a Silicon Germanium (SiGe) bipolar junction transistor in one example, although it can also be embodied as other types of transistors, and the concepts described herein are not limited to use with any particular type of transistor. SiGe bipolar transistors can have higher forward gain and lower reverse gain than silicon bipolar transistors. Thus, SiGe bipolar transistors can have better low-current and high-frequency performance. Heterojunction SiGe bipolar transistors can also have an adjustable band gap, which provides more flexible bandgap tuning than silicon bipolar transistors. However, the operating characteristics of SiGe transistors can be particularly sensitive to process, voltage, and temperature variations, and bias stabilization can be particularly important for SiGe and other high-gain transistors.

The current through the collector of the output amplifier stage Q10 is an exponential function of the voltage applied at its base (i.e., at the node A). As such, even a minor change in voltage applied at the node A can result in a significant variation in current through the output amplifier stage Q10 during operation. Additionally, the operating characteristics of SiGe transistors are particularly sensitive to process, voltage, and temperature variations, as are other types of transistors. As examples, the alpha a, beta 8, and other characteristics of the output amplifier stage Q10 are sensitive to process, voltage, and temperature variations. Thus, the direct current (DC) biasing (i.e., particularly the DC base-to-emitter voltage Vbe) of the output amplifier stage Q10 should be stabilized and maintained under tight control, for proper operation of the amplifier 100 over a wide range of operating conditions. In this context, the bias feedback network 130 is designed to control the operation of the biasing leg 120 to provide a precise, controllable bias voltage at the node A of the amplifier 100, which can sometimes vary over time during operation.

The biasing leg 120 includes a number of transistors, resistors, and other components. The biasing leg 120 is coupled between an upper voltage V+ and a lower voltage V− (or ground) potential. The V+ and V− potentials can be the same as, or different than, the upper and lower rail voltages or potentials between which the output amplifier stage Q10 is coupled. The input 110 for the amplifier 100 is coupled to the biasing leg 120, and any input signal, such as an RF input signal, can be applied at the input 110 for amplification by the amplifier 100.

The biasing leg 120 is configured to provide a biased input signal 111 to the output amplifier stage Q10. The biasing leg 120 generates the biased input signal 111 based on the input signal provided at the input 110 and a bias control signal 131 provided from the bias feedback network 130. The biased input signal 111 includes a biasing component for the output amplifier stage Q10, also referenced as Vbias, along with a signal component for amplification by the output amplifier stage Q10.

The biasing leg 120 sets the biasing component of the biased input signal 111, which can be a DC bias potential, based at least in part on the bias control signal 131 provided from the bias feedback network 130. The biasing component of the biased input signal 111 thus sets a bias potential at the base of the output amplifier stage Q10, which is base-biased. The biasing component can be set based on a voltage drop between the upper voltage V+ and the lower voltage V−, within the biasing leg 120, taken at a particular node within the biasing leg 120. As one example, an amount of current that flows through the biasing leg 120 is controlled by the bias control signal 131, and the biased input signal 111 can be coupled from a particular node within the biasing leg 120. The signal component of the biased input signal 111, which can be an RF signal component for amplification, is the signal amplified by the output amplifier stage Q10 and the amplifier 100, which is present on the same node at which the biased input signal 111 is taken. A more particular example of the biasing leg 120 is described below with reference to FIG. 3.

The bias feedback network 130 can be embodied as a difference amplifier, among other components, and can also include an RF bypass stage in some cases. The RF bypass stage can bypass components of the signal being amplified by the amplifier 100, to focus on bias control for the amplifier 100. The bias feedback network 130 is configured to generate the bias control signal 131 as an input for the biasing leg 120. For example, the difference amplifier in the bias feedback network 130 can compare the reference voltage Vref provided by the reference generator 132 and the biasing component Vbias of the biased input signal 111 at the node A and generate the bias control signal 131 based on a difference or comparison of Vref and Vbias. Thus, the bias control signal 131 is representative of the difference between the reference voltage Vref and the biasing component Vbias. The control loop provided by the bias feedback network 130 acts to minimize or reduce the difference between Vref and Vbias, based on a desired or target bias for the output amplifier stage Q10. A more particular example of the bias feedback network 130 is described below with reference to FIG. 3.

The reference generator 132 can be embodied using current mirrors, resistances, and other circuit components capable of generating the reference voltage Vref with suitable precision, preferably over different operating voltages, temperature ranges, etc. In some cases, the reference generator 132 can be programmable or controllable, to generate one or more different reference voltages over time, or a range of reference voltages over time. Based on the operation of the biasing leg 120 and the bias feedback network 130, as described above, the biasing component Vbias of the biased input signal 111 at the node A will track the reference voltage Vref. Thus, the bias potential for the output amplifier stage Q10 at node A can be set based on the reference voltage Vref generated by the reference generator 132.

The biasing leg 120 and bias feedback network 130 maintain Vbias at the node A during operation of the amplifier 100, based on the feedback control loop including the bias feedback network 130. Vbias can thus be maintained for the output amplifier stage Q10, even over a range of process variations of output amplifier stages (e.g., including Q10 and others), in addition to voltage and temperature variations for the amplifier 100 during operation.

Turning to a more particular example, FIG. 3 illustrates a detailed view of a single-ended amplifier 200 with bias stabilization according to various aspects of the embodiments described herein. The amplifier 200 can be used as a driver amplifier for optical communications, as an amplifier for RF communications, or for other purposes, without limitation. The amplifier 200 incorporates circuitry for bias stabilization, as described in further detail below, and the amplifier 200 is provided as an example of an amplifier that can incorporate the concepts of bias stabilization as described herein. Other types and configurations of amplifiers can also incorporate the bias stabilization concepts described herein.

The amplifier 200 includes an input 210, an output 212, a biasing leg 220, a bias feedback network 230, and output amplifier stage Q10, among possibly other components. The illustration of the amplifier 200 in FIG. 3 is not exhaustive, and the amplifier 200 can include additional components that are not illustrated in some cases. In other cases, one or more of the components illustrated can be omitted. The amplifier 200 can be implemented in a variety of ways, including as an integrated circuit device formed on a semiconductor substrate, discrete components, or a combination of discrete components and integrated circuits.

Similar to the amplifier 100 in FIG. 2, the output amplifier stage Q10 includes a base terminal, a collector terminal, and an emitter terminal. The collector of the output amplifier stage Q10 is coupled to an upper rail voltage or other power source for the amplifier 100, and the collector of the output amplifier stage Q10 is coupled to a lower rail voltage or ground for the amplifier 100. In some cases, a resistor or resistor network can be coupled between the collector of Q10 and the upper rail voltage or power source. Similarly, a resistor or resistor network can be coupled between the emitter of Q10 and the lower rail voltage or ground in some cases.

The output amplifier stage Q10 is base-biased between the upper rail voltage or other power source and the lower rail voltage for the amplifier 100. The base terminal of the output amplifier stage Q10 is identified as the node A in FIG. 3. As described in further detail below, the output amplifier stage Q10 is biased at the input terminal A based on the operation of the biasing leg 220 and the bias feedback network 230. The output amplifier stage Q10 can be embodied as SiGe bipolar junction transistor in one example, although it can also be embodied as other types of transistors. As noted above, the operating characteristics of SiGe transistors can be particularly sensitive to process, voltage, and temperature variations, and bias stabilization can be particularly important for SiGe and other high-gain transistors. While Q10 can be embodied as a SiGe bipolar junction transistor, the concepts can be extended to other types of transistors, including FETs. Thus, references to the base of Q10, as described below, also apply to the gate of a FET, if Q10 is embodied as a FET. References to the emitter also apply to the source of a FET, and references to the collector of a bipolar transistor also apply to the drain of a FET.

The biasing leg 220 is coupled between an upper voltage V+ and a lower voltage V− (or ground) potential. The V+ and V− potentials can be the same as, or different than, the upper and lower rail voltages or potentials between which the output amplifier stage Q10 is coupled. The input 210 for the amplifier 200 is coupled to the biasing leg 220, and any input signal, such as an RF signal, can be applied at the input 210 for amplification by the amplifier 200.

In the example shown, the biasing leg 220 includes transistors Q11 and Q12 and resistors R11 and R12, among possibly other components. Like the output amplifier stage Q10, the transistors Q11 and Q12 can also be embodied as SiGe bipolar junction transistors, although other types of transistors can be relied upon. The transistor Q11 is coupled as a common collector in the biasing leg 220, and the transistor Q12 is coupled as a common emitter in the biasing leg 220. The collector of the transistor Q11 is coupled to the source voltage V+, the input 210 of the amplifier 200 is coupled to the base of the transistor Q11, and the emitter of the transistor Q11 is coupled to a first terminal of the resistor R12. The individual resistances of R12 and R11 can be selected to permit a range of biasing voltages at the biasing node B within the biasing leg 120, based on the current Ia through it, as described below. The resistance of R12 can be larger than the resistance R11, in one example, to permit the range of biasing voltages at the node B.

The collector of the transistor Q12 is coupled to a second terminal of the resistor R12 at the node B. The base of the transistor Q12 is coupled to a bias control signal 241 generated by the bias feedback network 230, and the emitter of the transistor Q12 is coupled to a first terminal of the resistor R13. A second terminal of the R13 is coupled to ground in the example shown. As shown, the resistors R12 and R13 are coupled in series with the transistors Q11 and Q12 in the biasing leg 220.

The resistor R12 is also referred to as a voltage drop resistor, because the voltage drop across the resistor R12 (and the transistor Q11), from the source voltage V+, determines or sets the voltage at the node B. That is, starting from the source voltage V+, the voltage at node B is determined by the voltage drop across the transistor Q11 and the resistor R12, which depends on the current Ia through the biasing leg 220. The current Ia through the biasing leg 220 can be controlled by a bias control signal 231 provided from the bias feedback network 230, which is provided at the base of the transistor Q12.

The amplifier 200 also includes a resistor R11 coupled between the node B and the node A, at the base of the output amplifier stage Q10. The amplifier 200 also includes a capacitor C11 coupled between the emitter of the transistor Q11 and the node A. The resistor R11 provides an impedance to limit current flowing into the base of the output amplifier stage Q10. R11 can be a relatively high impedance to limit the base current. The capacitor C11 presents a direct coupling (i.e., similar to a short circuit) for RF signals between the emitter of the transistor Q11 and the base of the output amplifier stage Q10. The capacitance of C11 can be selected based on the operating frequency range of the amplifier 200 for suitable operation.

An input signal provided at the input 210 will be amplified, in part, by the transistor Q11 and provided as an output at the emitter of the transistor Q11. The capacitor C11 then couples the RF component of this signal from the emitter of the transistor Q11 to node A of the output amplifier stage Q10, for amplification by the output amplifier stage Q10. The output 212 of the amplifier 200 can be taken at the collector of the output amplifier stage Q10 as shown in FIG. 3, for example, or at the emitter of the output amplifier stage Q10 in some cases.

The biasing leg 220 is configured to provide a biased input signal 211 to the output amplifier stage Q10. The biasing leg 220 generates the biased input signal 211 based on the input signal provided at the input 110 and the bias control signal 231 provided from the bias feedback network 130. The biased input signal 211 includes a biasing component for the output amplifier stage Q10, also referenced as Vbias, along with a signal component for amplification by the output amplifier stage Q10.

The biasing leg 220 sets the biasing component of the biased input signal 211, which can be a DC bias potential, based on the bias control signal 231 provided from the bias feedback network 230. The biasing component of the biased input signal 211 thus sets a bias potential at the base of the output amplifier stage Q10, which is base-biased. The biasing component can be set based on a voltage drop between the upper voltage V+ and the lower voltage V−, taken at node B along the biasing leg 120. In the example shown, the Ia current through the biasing leg 220 is controlled by the bias control signal 231 applied to Q12, which ultimately establishes the voltage at the node B as described above.

The biased input signal 211 for the output amplifier stage Q10 is taken at the node B along the biasing leg 120. The signal component of the biased input signal 211 is provided at the emitter of Q11 and coupled to node A through the capacitor C11, based on the input signal provided at the input 210.

The bias feedback network 230 includes a difference amplifier 234, an RF bypass stage 236, and a reference voltage generator 232, and a resistor R12. The difference amplifier 234 can be embodied as a high-gain operational or similar amplifier with inverting and non-inverting inputs, as one example. As shown in FIG. 3, the non-inverting (i.e., +) input of the difference amplifier 234 is coupled to node A at the base of the output amplifier stage Q10, through the resistor R15. The inverting (i.e., −) input of the difference amplifier 234 is coupled to a reference voltage Vref generated by the reference voltage generator 238. In one aspect of the embodiments, the operating bandwidth of the difference amplifier 234 (e.g., the difference between the frequency limits over which the difference amplifier 234 can amplify a signal) is relatively smaller than that of the overall amplifier 200 (and particularly smaller than that of the output amplifier stage Q10), such that the difference amplifier 234 does not provide or present a high gain to high-frequency signals applied at the input 210 and coupled at the node A. As such, the difference amplifier 234 filters out and does not amplify (or does not amplify as much) the high-frequency signal components applied at the input 210.

The reference voltage generator 232 can be embodied using current mirrors, resistances, and other circuit components capable of generating the reference voltage Vref with suitable precision, preferably over different operating voltages, temperature ranges, etc. In some cases, the reference voltage generator 232 can be programmable or controllable, to generate one or more different reference voltages over time, or a range of reference voltages over time.

The difference amplifier 234 outputs a bias control signal or bias control voltage 231. The bias control signal 231 is representative of the difference in voltage between the inverting and non-inverting inputs of the difference amplifier 234, which is the difference between Vref from the reference voltage generator 232 and Vbias at the node A. The bias control signal 231 is provided to the RF bypass stage 236, which includes the capacitor C12 and the resistor R14. The capacitor C12 provides an RF short to ground for high-frequency components on the bias control signal 242. The capacitance of C12 can be selected based on the operating frequency range of the amplifier 200. The resistor R14 provides an impedance to limit current flowing into the base of the transistor Q12 in the biasing leg 120. R14 can be a relatively high impedance to limit the base current.

In operation, the difference amplifier 234 seeks to minimize or reduce the difference between Vref and Vbias, by controlling the bias control signal 231 provided to the transistor Q12. An increased voltage of the bias control signal 231, when applied to the base of Q12, will result in an increased Ia current through the biasing leg 220. An increased Ia will result in a lower voltage or potential at the node B (e.g., a voltage closer to V−) based on a larger voltage drop across Q11 and R12 (and primarily across R12). A decreased voltage of the bias control signal 231, when applied to Q12, will result in a decreased Ia current through the biasing leg 220. A decreased Ia will result in a higher voltage or potential at the node B, based on a smaller voltage drop across Q11 and R12 (and primarily across R12).

Thus, the voltage at the node B and the bias voltage Vbias at the node A can be controlled by the bias control signal 231 generated by the difference amplifier 234. The difference amplifier 234 outputs the bias control signal 231 based on the difference in voltage between the inverting and non-inverting inputs of the difference amplifier 134, which is the difference between Vref from the reference voltage generator 232 and Vbias at the node A. The bias feedback network 230 is thus configured to minimize the difference between Vref and Vbias, for proper biasing of the base terminal of the output amplifier stage Q10.

When embodied as integrated devices, the amplifiers 100 and 200 can be formed using any suitable semiconductor manufacturing process or processes. When embodied as a combination of discrete components and integrated devices, the amplifiers 100 and 200 can include integrated devices formed using any suitable manufacturing process or processes. In other embodiments, the amplifiers 100 and 200 can be simulated on one or more computing devices using one or more circuit simulator, semiconductor device modeling, semiconductor process simulation, or related Technology Computer Aided Design (TCAD) software tools. For example, one or more aspects of a semiconductor manufacturing process, such as the dopant distribution, the stress distribution, the device geometry, and other aspects of a manufacturing process to form the amplifiers 100 and 200 can be simulated. As other examples, operating characteristics, such as the voltage and current biases, of the amplifiers 100 and 200 can be simulated. Simulations can be relied upon to model the characteristics and performance of the semiconductor devices (e.g., transistors) and other elements (e.g., resistors, inductors, capacitors, etc.) of the amplifiers 100 and 200.

The amplifiers 100 and 200 described herein, among others consistent with the concepts described herein, can be embodied in hardware or simulated as a number of circuit elements in software. When simulated using software, each circuit element can be embodied as a module or listing of code associated with certain parameters to simulate the element. The software to simulate the circuit elements can include program instructions embodied in the form of, for example, source code that includes human-readable statements written in a programming language or machine code that includes machine instructions recognizable by a suitable execution system, such as a processor in a computer system or other system. If embodied in hardware, each element can represent a circuit or a number of electrically interconnected circuits.

One or more computing devices can execute the software to simulate the circuit elements that form the amplifiers described herein, among others. The computing devices can include at least one processing circuit. Such a processing circuit can include, for example, one or more processors and one or more storage or memory devices coupled to a local interface. The local interface can include, for example, a data bus with an accompanying address/control bus or any other suitable bus structure.

The storage or memory devices can store data or components that are executable by the processors of the processing circuit. For example, data associated with one or more circuit elements of the distributed amplifiers can be stored in one or more storage devices and referenced for processing by one or more processors in the computing devices. Similarly, the software to simulate the circuit elements and/or other components can be stored in one or more storage devices and be executable by one or more processors in the computing devices.

The transistors described herein can be formed using a number of different semiconductor materials and semiconductor manufacturing processes. Example semiconductor materials include the group IV elemental semiconductor materials, including Silicon (Si) and Germanium (Ge), compounds thereof, and the group III elemental semiconductor materials, including Aluminum (Al), Gallium (Ga), and Indium (In), and compounds thereof.

The optimizations in amplifiers can be applied to active semiconductor devices, such as transistors and amplifiers formed in SiGe semiconductor materials, amplifiers formed in III-Nitride (Aluminum (Al)-, Gallium (Ga)-, Indium (In)-, and their alloys (e.g., AlGaIn)) semiconductor materials, and GaAs, InP, InGaP, AlGaAs, and related semiconductor materials. The principles and concepts can also be applied to transistors and other active devices formed from other semiconductor materials.

The embodiments described herein are also applicable for use with amplifiers including GaN-on-Si transistors, among other types of transistors, but the embodiments can also be applied to GaN-on-Silicon Carbide (SiC) transistors, as well as other types of transistors. As used herein, the phrase “gallium nitride material(s)” or GaN semiconductor material(s) refers to gallium nitride and any of its alloys, such as aluminum gallium nitride (Alₓ Ga₍₁₋ₓ₎ N), indium gallium nitride (In_{y} Ga_{(1-y)} N), aluminum indium gallium nitride (Alₓ In_{y} Ga_{(1-x-y)} N), gallium arsenide phosphide nitride (GaAsₐ P_{b} N_{(1-a-b)}), aluminum indium gallium arsenide phosphide nitride (Alₓ In_{y} Ga_{(1-x-y)} ASₐ P_{b} N_{(1-a-b)}), among others. Typically, when present, arsenic and/or phosphorous are at low concentrations (e.g., less than 5 weight percent). The term “gallium nitride” or GaN semiconductor refers directly to gallium nitride, exclusive of its alloys.

The features, structures, and components described above may be combined in one or more embodiments in any suitable manner, and the features discussed in the various embodiments are interchangeable where technically suitable. In the foregoing description, numerous specific details are provided in order to fully understand the embodiments of the present disclosure. However, a person skilled in the art will appreciate that the technical solution of the present disclosure may be practiced without one or more of the specific details, or other methods, components, materials, and the like may be employed. In other instances, well-known structures, materials, or operations are not shown or described in detail to avoid obscuring aspects of the present disclosure.

Although relative terms such as “on,” “below,” “upper,” “lower,” “top,” “bottom,” “right,” and “left” may be used to describe the relative spatial relationships of certain structural features, these terms are used for convenience only, as a direction in the examples. It should be understood that if the device is turned upside down, the “upper” component will become a “lower” component. When a structure or feature is described as being “over” (or formed over) another structure or feature, the structure can be positioned over the other structure, with or without other structures or features intervening between them. When two components are described as being “connected to” or “coupled to” each other, the components can be electrically connected or coupled to each other, with or without other components being electrically coupled and intervening between them. When two components are described as being “directly connected to” or “directly coupled to” each other, the components can be electrically connected or coupled to each other, without other components being electrically coupled between them. Terms such as “a,” “an,” “the,” and “said” are used to indicate the presence of one or more elements and components. The terms “comprise,” “include,” “have,” “contain,” and their variants are used to be open ended and may include or encompass additional elements, components, etc., in addition to the listed elements, components, etc., unless otherwise specified.

Although embodiments have been described herein in detail, the descriptions are by way of example. The features of the embodiments described herein are representative and, in alternative embodiments, certain features and elements can be added or omitted. Additionally, modifications to aspects of the embodiments described herein can be made by those skilled in the art without departing from the spirit and scope of the present invention defined in the following claims, the scope of which are to be accorded the broadest interpretation so as to encompass modifications and equivalent structures.

1. An amplifier with bias stabilization, comprising:
an output amplifier stage comprising an input terminal;
a biasing leg comprising a biasing node coupled to the input terminal of the output amplifier stage; and
a bias feedback network coupled between the input terminal of the output amplifier stage and the biasing leg.

2. The amplifier according to claim 1, wherein the biasing leg comprises a first biasing transistor and a second biasing transistor.

3. The amplifier according to claim 2, wherein:
the first biasing transistor comprises a collector coupled to a source voltage, an emitter coupled to the second biasing transistor, and a base coupled to an input of the amplifier; and
the second biasing transistor comprises a collector coupled to the first biasing transistor, an emitter coupled to ground, and a base coupled to a bias control signal from the bias feedback network.

4. The amplifier according to claim 3, wherein the biasing leg further comprises a voltage drop resistor coupled in series between the emitter of the first biasing transistor and the collector of the second biasing transistor.

5. The amplifier according to claim 4, wherein the biasing node of the biasing leg is positioned between the voltage drop resistor and the collector of the second biasing transistor.

6. The amplifier according to claim 1, wherein the bias feedback network comprises a difference amplifier, a bypass stage, and a reference voltage generator.

7. The amplifier according to claim 6, wherein:
a first input of the difference amplifier is coupled to the input terminal of the output amplifier stage;
a second input of the difference amplifier is coupled to an output of the reference voltage generator; and
the difference amplifier generates a bias control signal based on a difference between the first input and the second input of the difference amplifier.

8. The amplifier according to claim 7, wherein the bias control signal is coupled as an input to the biasing leg.

9. The amplifier according to claim 7, wherein the bias control signal controls a potential at the biasing node in the biasing leg, coupled to the input terminal of the output amplifier stage.

10. The amplifier according to claim 7, wherein an operating bandwidth of the difference amplifier is smaller than an operating bandwidth of the output amplifier stage.

11. The amplifier according claim 1, wherein the output amplifier stage comprises a bipolar junction transistor.

12. The amplifier according to claim 1, wherein the output amplifier stage comprises a base-biased bipolar junction transistor.

13. An amplifier with bias stabilization, comprising:
a single-ended output transistor stage comprising an input terminal at a base of the transistor stage, the transistor stage being base-biased;
a biasing leg comprising an input for the amplifier and a biasing node coupled to the input terminal of the output transistor stage; and
a bias feedback network coupled between the input terminal of the output transistor stage and the biasing leg.

14. The amplifier according to claim 13, wherein the biasing leg comprises a common collector input transistor and a common emitter biasing transistor.

15. The amplifier according to claim 14, wherein the biasing leg further comprises a voltage drop resistor coupled in series between an emitter of the common collector input transistor and a collector of the common emitter biasing transistor.

16. The amplifier according to claim 15, wherein the biasing node of the biasing leg is positioned between the voltage drop resistor and the collector of the common emitter biasing transistor.

17. The amplifier according to claim 13, wherein:
the bias feedback network comprises a difference amplifier and a reference voltage generator;
the difference amplifier generates a bias control signal based on a difference between the input terminal of the output transistor stage and the reference voltage generator; and
the bias control signal is coupled to the biasing node of the biasing leg.

18. An amplifier with bias stabilization, comprising:
a single-ended output transistor stage;
a biasing leg comprising an input for the amplifier and a biasing node coupled to an input terminal of the output transistor stage; and
a bias feedback network coupled between the input terminal of the output transistor stage and the biasing leg.

19. The amplifier according to claim 18, wherein the biasing leg comprises:
a common emitter input transistor and a common collector biasing transistor; and
a voltage drop resistor coupled in series between an emitter of the common emitter input transistor and a collector of the common collector biasing transistor, wherein the biasing node of the biasing leg is positioned between the voltage drop resistor and the collector of the common collector biasing transistor.

20. The amplifier according to claim 18, wherein:
the bias feedback network comprises a difference amplifier and a reference voltage generator;
the difference amplifier generates a bias control signal based on a difference between the input terminal of the output transistor stage and the reference voltage generator; and
the bias control signal is coupled to the biasing node of the biasing leg.
